(19) United States
(12) Patent Application Publication
(10) Pub. No.: US 2022/0173144 A1
(43) Pub. Date: Jun. 2, 2022

(54) IMAGE-SENSING DEVICE

(71) Applicant: Silicon Optronics, Inc., Hsinchu (TW)

(72) Inventor: Bo-Ray LEE, Hsinchu (TW)

(21) Appl. No.: 17/349,107

(22) Filed: Jun. 16, 2021

(30) Foreign Application Priority Data
Dec. 1, 2020 (TW) 109142186

(51) Int. Cl. H01L 27/146; G02B 5/20

(52) U.S. Cl. CPC H01L 27/14621; H01L 27/14645; G02B 3/0006; G02B 5/201; H01L 27/14627

(57) ABSTRACT

An image-sensing device is provided. An image sensor array is formed in a substrate. A micro lens array is formed on the image sensor array. A color filter array is formed between the micro lens array and the image sensor array. The color filter array includes a plurality of blue filters, a plurality of red filters, a plurality of first combined filters and a plurality of second combined filters. Each of the first combined filters and the second combined filters includes two first sub-filters and two second sub-filters. The first sub-filter and the second sub-filter have a similar extinction coefficient in a first specific wavelength range, and have different extinction coefficients in a second specific wavelength range. The area of the first sub-filter and the second sub-filter is smaller than the area of the blue filter and the red filter.

### CROSS REFERENCE TO RELATED APPLICATIONS

This application claims priority of Taiwan Patent Application No. 109142186, filed on Dec. 1, 2020, the entirety of which is incorporated by reference herein.

### BACKGROUND OF THE INVENTION

### Field of the Invention

The invention relates to an image-sensing device, and more particularly to an image-sensing device with combined color filter.

### Description of the Related Art

An image sensor is a semiconductor device that converts light images into electrical signals. Image sensors can generally be classified as either charge-coupled devices (CCD) or complementary metal-oxide-semiconductor (CMOS) image sensors. Among these image sensors, complementary metal-oxide-semiconductor image sensor includes a photodiode for detecting incident light and converting it into an electrical signal, and a logic circuit for transmitting and processing the electrical signal.

When the pixel size of an image sensor is reduced, the quantum efficiency (QE) (e.g., photoelectric conversion ratio) of the image sensor will decrease due to diffraction limitation. In addition, in low light conditions, the quantum efficiency of the image sensor will also decrease.

Therefore, an image sensor with high quantum efficiency is desired.

### BRIEF SUMMARY OF THE INVENTION

Image-sensing devices are provided. An embodiment of an image-sensing device is provided. The image-sensing device includes a substrate, an image sensor array, a micro lens array and a color filter array. The image sensor array is formed over the substrate. The micro lens array is formed over the image sensor array. The color filter array is formed between the micro lens array and the image sensor array. The image sensor array includes a plurality of image-sensing cells. The micro lens array includes a plurality of micro lenses. The color filter array includes a plurality of blue filters, a plurality of red filters, a plurality of first combined filters and a plurality of second combined filters. Each of the first combined filters and each of the second combined filters comprise two first sub-filters and two second sub-filters. The first sub-filters and the second sub-filters have a similar extinction coefficient in a first specific wavelength range, and have different extinction coefficients in a second specific wavelength range. The areas of each of the first sub-filters and each of the second sub-filters are smaller than areas of each of the blue filters and each of the red filters.

Moreover, an embodiment of an image-sensing device is provided. The image-sensing device includes a substrate, an image sensor array, a micro lens array, and a color filter array. The image sensor array is formed over the substrate, and includes a plurality of image-sensing cells. The micro lens array is formed over the image sensor array, and includes a plurality of micro lenses. Each of the micro lenses corresponds to an individual image-sensing cell. The color filter array is formed between the micro lens array and the image sensor array, and includes a plurality of blue filters, a plurality of red filters, a plurality of first combined filters and a plurality of second combined filters. Each of the first combined filters and each of the second combined filters comprise two first sub-filters and two second sub-filters. Each of the first combined filters, each of the second combined filters, each of the blue filters and each of the red filters have the same area. Each of the blue filters is surrounded by the first sub-filters, and each of the red filters is surrounded by the second sub-filters.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a cross-sectional view of a front-side illumination (FSI) image-sensing device according to some embodiment of the invention.

FIG. 2A shows a rolling shutter image-sensing cell according to some embodiments of the invention.

FIG. 2B shows a global shutter image-sensing cell according to some embodiments of the invention.

FIG. 3 shows a cross-sectional view of a back-side illumination (BSI) image-sensing device according to some embodiment of the invention.

FIG. 4 shows a top view of the color filter array according to some embodiments of the invention.

FIG. 5 shows a graph illustrating the extinction coefficients of the blue filter 12B, the red filter 12R, and the sub-filters 12bb and 12rr according to some embodiments of the invention.

FIG. 6 shows a graph illustrating the extinction coefficients of the blue filter 12B, the red filter 12R, and the sub-filters 12bb and 12rr according to some embodiments of the invention.

FIG. 7 shows a graph illustrating the refraction indexes of the blue filter 12B, the red filter 12R, and the sub-filters 12bb and 12rr according to some embodiments of the invention.

FIG. 8 shows a graph illustrating the refraction indexes of the blue filter 12B, the red filter 12R, and the sub-filters 12bb and 12rr according to some embodiments of the invention.

FIG. 9 shows a cross-sectional view along the line A-AA of the color filter array in FIG. 4 according to some embodiments of the invention.

FIG. 10 shows that the green filters of the traditional color filter array are replaced with the first combined filter and the second combined filter to obtain the color filter array according to the embodiments of the invention.

FIG. 11 shows that the green filters of the traditional color filter array are replaced with the first combined filter and the second combined filter to obtain the color filter array according to the embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

It should be understood that, the elements or devices of the drawings may exist in various forms well known to those skilled in the art. In addition, relative terms such as “lower” or “bottom” and “higher” or “top” may be used in the embodiments to describe the relative relationship between one element of the figure and another element. It can be understood that if the illustrated device is turned upside down and turned upside down, the element described on the “lower” side will become the element on the “higher” side. The embodiments of the disclosure can be understood together with the drawings, and the drawings of the disclosure are also considered as a part of the disclosure description. It should be understood that the drawings disclosed in this disclosure are not drawn to scale. In fact, the dimensions of the elements may be arbitrarily enlarged or reduced in order to clearly show the features of the present invention.

Further tore, the elements or devices of the drawings may exist in various forms well known to those skilled in the art. Moreover, understandably, although the terms “first”, “second”, “third”, etc. may be used herein to describe various elements or parts, these elements, components, or parts should not be limited by these terms, and these terms are only Is used to distinguish different elements, components, areas, layers or parts. Therefore, a first element, component, area, layer or part discussed below may be referred to as a second element, component, area, layer or part without departing from the teachings of this disclosure.

In some embodiments of the present disclosure, terms such as “connect” and “interconnect” with regard to bonding and connection may refer to the two structures being in direct contact, or may refer to the two structures not being in direct contact unless specifically defined. There are other structures between these two structures. In addition, the term “joining and connecting” may also include a case where both structures are movable or both structures are fixed.

Unless otherwise defined, all terms (including technical and scientific terms) used herein have the same meaning as commonly understood by those skilled in the art to which this disclosure belongs. It is understandable that these terms, such as those defined in commonly used dictionaries, should be interpreted as having a meaning consistent with the background or context of the related technology and this disclosure, It should not be interpreted in an idealized or excessively formal manner unless specifically defined in the disclosed embodiments.

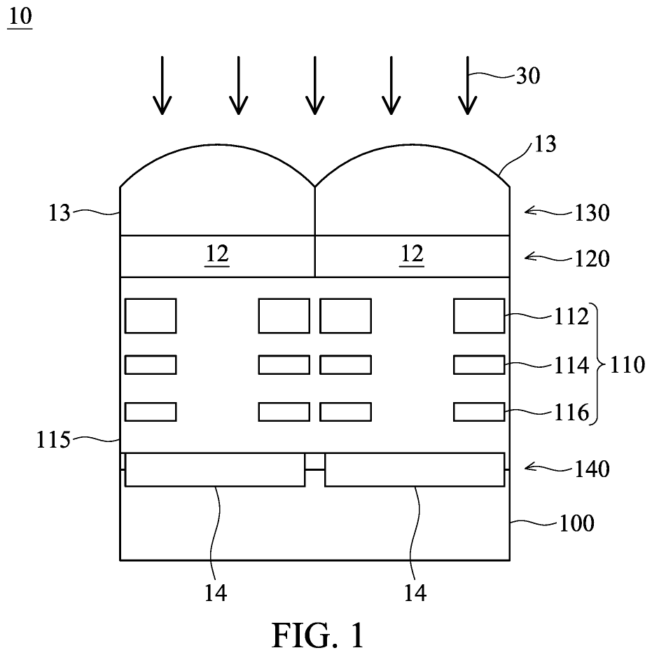

FIG. 1 shows a cross-sectional view of a front-side illumination (FSI) image-sensing device 10 according to some embodiment of the invention. It should be understood that, according to some embodiments, additional features may be added to the image-sensing device 10 described below. According to some embodiments, some features described below may be replaced or deleted.

In FIG. 1, the front-side illumination image-sensing device 10 includes a substrate 100. In some embodiments, the substrate 100 is a semiconductor substrate. For example, the material of the substrate 100 may include monocrystalline, polycrystalline, or amorphous silicon (Si) or germanium (Ge) or a combination thereof. In some embodiments, the substrate 100 is formed of a compound semiconductor. For example, in some embodiments, the material of the substrate 100 may include silicon carbide (SiC), gallium arsenide (GaAs), gallium phosphide (GaP), indium phosphide (InP), indium arsenide (InAs), or a combination thereof in addition, according to some embodiments, the material of the substrate 100 may be formed of alloy semiconductors. For example, in some embodiments, the material of the substrate 100 may include germanium silicide (SiGe), aluminum gallium arsenide (AlGaAs), gallium indium arsenide (GaInAs), gallium indium phosphide (GaInP), gallium arsenide (GaAsP)) or a combination thereof.

In FIG. 1, the front-side illumination image-sensing device 10 further includes an image sensor array 140 formed in the substrate 100. The image sensor array 140 includes a plurality of image-sensing cells 14 arranged in multiple rows and multiple columns, and each image-sensing cell 14 includes a photodiode. The photodiode is configured to receive light and convert it into electrical signals. In some embodiments, the image-sensing cell 14 may be a rolling shutter image-sensing cell or a global shutter image-sensing cell.

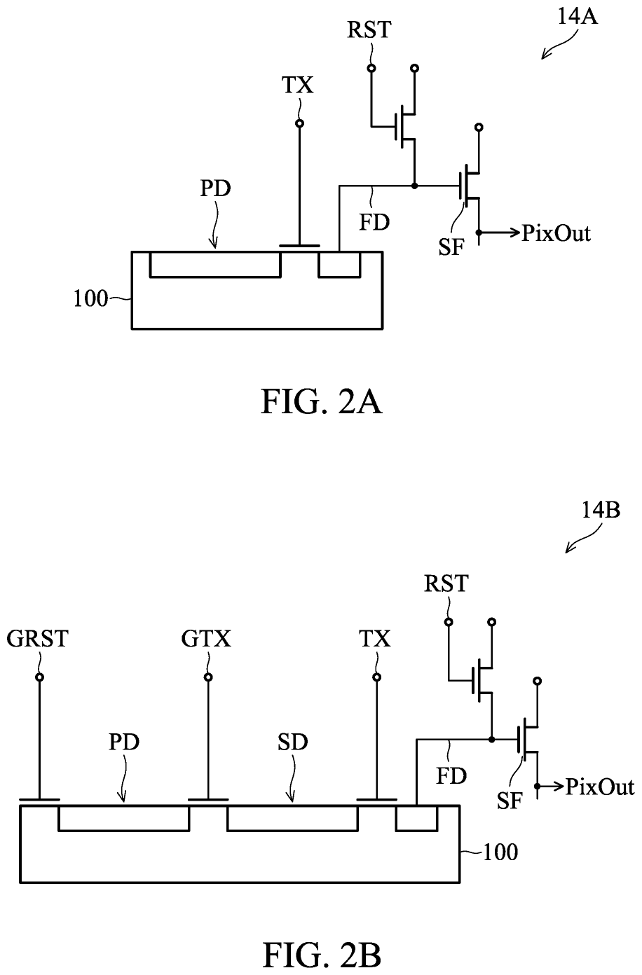

Referring to FIGS. 2A and 2B, FIG. 2A shows a rolling shutter image-sensing cell 14A according to some embodiments of the invention, and FIG. 2B shows a global shutter image-sensing cell 14B according to some embodiments of the invention. In the image-sensing cells 14A and 14B, the photodiode PD may include the source and drain of a metal oxide semiconductor (MOS) transistor, and the source and drain of the MOS transistor are configured to transmit current to other components, such as other MOS transistors. In some embodiments, the image-sensing cells 14A and 14B may include a transmission gate TX, a reset gate RST, a floating diffusion FD, a source follower SF, or a combination thereof. Furthermore, the image-sensing cells 14A and 14B can be further coupled to external devices or circuits, so as to transmit the output signal PixOut to other circuits, such as a signal processor (not shown). It is noted that FIGS. 2A and 2B only simply show some components of the image-sensing cells 14A and 14B, and are not intended to limit the invention. Any image-sensing cell suitable for rolling shutters or global shutters can be used as the image-sensing cell 14 of the invention.

Referring back to FIG. 1, the front-side illumination image-sensing device 10 further includes a dielectric layer 115, and the dielectric layer 115 is formed on the image sensor array 140. In other words, the dielectric layer 115 is configured to cover the image-sensing cells 14 of the image sensor array 140. In some embodiments, the material of the dielectric layer 115 may include silicon oxide, silicon nitride, silicon oxynitride, high-k dielectric materials, other suitable dielectric materials, or the foregoing combination. In some embodiments, the high dielectric constant dielectric material may include metal oxide, metal nitride, metal silicide, metal aluminate, zirconium silicate, zirconium aluminate, or a combination thereof.

In some embodiments, the dielectric layer 115 is formed by the physical vapor deposition (PVD), chemical vapor deposition (CVD), coating process, other suitable method, or a combination thereof. The physical vapor deposition process may include, for example, a sputtering process, an evaporation process, or pulsed laser deposition. The chemical vapor deposition process may include, for example, a low pressure chemical vapor deposition process (LPCVD), a low temperature chemical vapor deposition process (LTCVD), a rapid temperature rise chemical vapor deposition process (RTCVD), a plasma assisted chemical vapor deposition process (PECVD), or atomic layer deposition process (ALD) and so on.

In FIG. 1, the front-side illumination image-sensing device 10 further includes an interconnect structure 110, and the interconnect structure 110 is formed in the dielectric layer 115. In some embodiments, the interconnection structure 110 includes a plurality of conductive layers 112, 114, and 116. Each of the conductive layers 112, 114, and 116 includes a plurality of conductive electrodes, so as to transmit signals in the image-sensing cells 14 of the front-side illumination image-sensing device 10 and related circuits. It should be understood that although three layers of conductive layers 112, 114, and 116 are exemplarily illustrated in FIG. 1, the invention is not limited thereto. In accordance with different embodiments, according to need, suitable amount and structure of the conductive layer may be arranged to form the interconnect structure 110.

In some embodiments, the interconnect structure 110 may include a metallic conductive material, a transparent conductive material, or a combination thereof. The metallic conductive material may include copper (Cu), aluminum (Al), gold (Au), silver (Ag), titanium (Ti), tungsten (W), molybdenum (Mo), nickel (Ni), copper alloy, aluminum alloy, gold alloy, silver alloy, titanium alloy, tungsten alloy, molybdenum alloy, nickel alloy, or a combination thereof. The transparent conductive material may include a transparent conductive oxide (TCO). For example, the transparent conductive oxide may include indium tin oxide (ITO), tin oxide (SnO), zinc oxide (ZnO), indium zinc oxide (IZO), indium gallium zinc oxide (IGZO), indium tin zinc oxide (ITZO), antimony tin oxide (ATO), antimony zinc oxide (AZO), or a combination thereof.

In some embodiments, a physical vapor deposition (PVD) process, a chemical vapor deposition (CVD) process, a coating process, other suitable processes, or a combination thereof may be used to form the interconnect structure 110. In some embodiments, a patterning process may be used to form the interconnect structure 110. In some embodiments, the patterning process may include a photolithography process and an etching process. The photolithography process may include, but is not limited to, photoresist coating (for example, spin coating), soft baking, hard baking, mask alignment, exposure, post-exposure baking, photoresist development, cleaning, and drying. The etching process may include a dry etching process or a wet etching process, but it is not limited thereto.

In FIG. 1, the front-side illumination image-sensing device 10 further includes a color filter array 120 and a micro lens array 130. The color filter array 120 is formed over the dielectric layer 115, and the micro lens array 130 is formed over the color filter array 120. The color filter array 120 is formed by a plurality of color filers 12. Each color filter 12 is configured to pass light of a corresponding wavelength range. In addition, the micro lens array 130 is formed by a plurality of micro lenses 13, and the micro lenses 13 can be used to guide and focus the light 30 to the color filter array 120. In some embodiments, the composition of the micro lenses 13 may be a material with high light transmittance. For example, the high light transmittance material may include a transparent polymer material (for example, polymethylmethacrylate (PMMA)), a transparent ceramic material (for example, glass), other transparent materials, or a combination thereof.

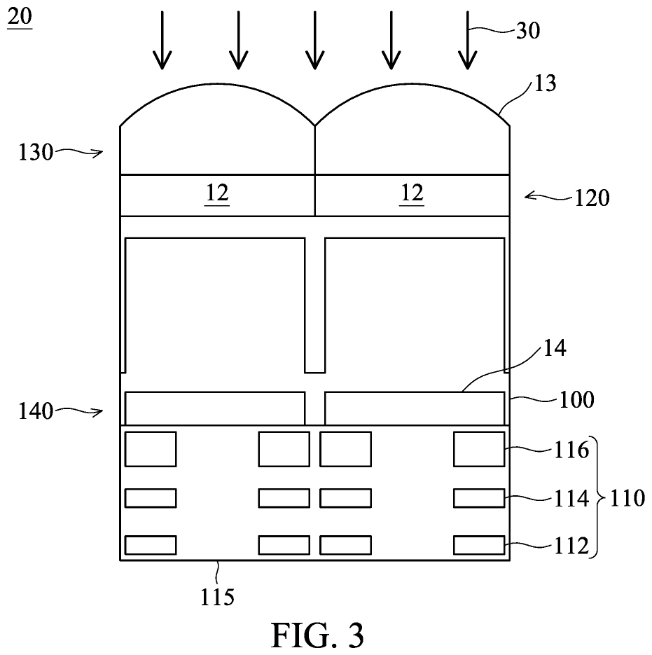

FIG. 3 shows a cross-sectional view of a back-side illumination (BSI) image-sensing device 20 according to some embodiment of the invention. It should be understood that, according to some embodiments, additional features may be added to the image-sensing device 20 described below. According to some embodiments, some features described below may be replaced or deleted.

In the back-side illumination image-sensing device 20, the color filter array 120 and the micro lens array 130 are disposed on the back side of the substrate 100 (for example, on the opposite side of the interconnect structure 110 of the substrate 100), so that the image sensor array 140 can receive more light 30. Compared with the front-side illumination image-sensing device 10 in FIG. 1, the back-side illumination image-sensing device 20 has improved performance, higher quantum efficiency (QE) (such as photoelectric conversion ratio), and better angular response in low-light conditions.

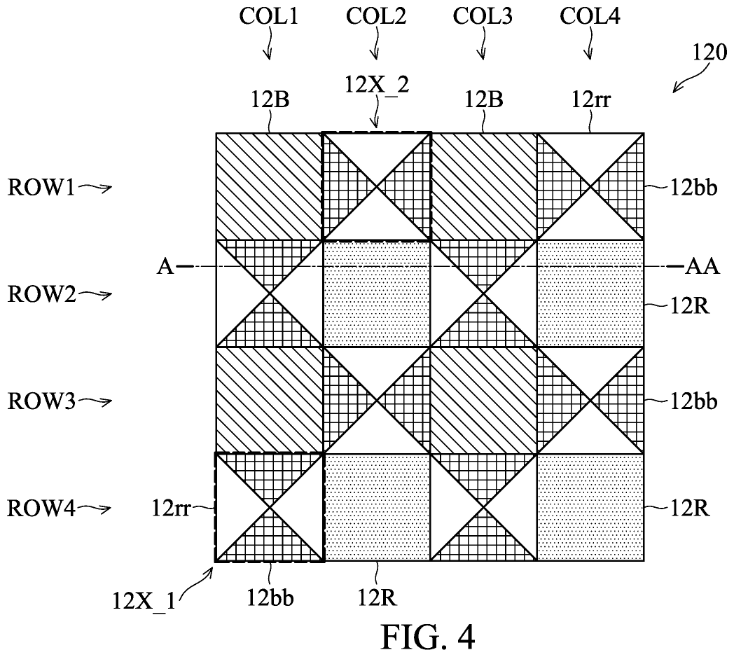

FIG. 4 shows a top view of the color filter array 120 according to some embodiments of the invention. The color filter array 120 includes the blue filters 12B, the red filters 12R, the first combined filters 12X_1 and the second combined filters 12X_2 arranged in a 4×4 array. In FIG. 4, the number of rows (e.g., 4 rows) and the number of columns (e.g., 4 columns) of the color filter array 120 are merely exemplary, and are not intended to limit the invention. In other embodiments, the color filter array 120 may have more or less rows and more or less columns.

In the color filter array 120 of FIG. 4, the blue filters 12B and the first combined filters 12X_1 are alternately disposed in the first column COL1, and the red filters 12R and the second combined filters 12X_2 are alternately disposed in the second column COL2. Similarly, the blue filters 12B and the first combined filters 12X_1 are alternately disposed in the third column COL3, and the red filters 12R and the second combined filters 12X_2 are alternately disposed in the fourth column COL4.

In the color filter array 120 of FIG. 4, the blue filters 12B and the second combined filters 12X_2 are alternately disposed in the first row ROW1, and the red filters 12R and the first combined filters 12X_1 are alternately disposed in the second row ROW2. Similarly, the blue filters 12B and the second combined filters 12X_2 are alternately disposed in the third row ROW3, and the red filters 12R and the first combined filters 12X_1 are alternately disposed in the fourth row ROW4.

In the embodiments of the invention, the blue filter 12B and the red filter 12R are respectively a single filter. Compared with the blue filter 12B and the red filter 12R, each of the first combined filter 12X_1 and the second combined filter 12X_2 is composed of two sub-filters 12rr and two sub-filters 12bb. In the first combined filter 12X_1, two sub-filters 12rr are arranged on the left and right sides, and two sub-filters 12bb are arranged on the upper and lower sides. In the second combined filter 12X_2, two sub-filters 12rr are arranged on the upper and lower sides, and two sub-filters 12bb are arranged on the left and right. In other words, the first combined filter 12X_1 is rotated 90 degrees clockwise or counterclockwise to obtain the second combined filter 12X_2.

In the color filter array 120, the sub-filters 12bb are arranged around the blue filters 12B, and the sub-filters 12rr are arranged around the red filters 12R. Therefore, the blue filter 12B is surrounded by four sub-filters 12bb, and the red filter 12R is surrounded by four sub-filters 12rr. For example, the red filter 12R of the second row ROW2 and the second column COL2 is surrounded by the sub-filters 12rr disposed in the second combined filter 12X_2 of the first row ROW1 and the second column COL2, the two first combined filters 12X_1 of the second row ROW2 and the first and third columns COL1 and COL3, and the second combined filter 12X_2 of the third row ROW3 and the second column COL2. Similarly, the blue filter 12B of the third row ROW3 and the third column COL3 is surrounded by the sub-filters 12bb disposed in the first combined filter 12X_1 of the second row ROW2 and the third column COL3, the two second combined filters 12X_2 of the third row ROW3 and the second and fourth columns COL2 and COL4, and the first combined filter 12X_1 of the fourth row ROW4 and the third column COL3.

In some embodiments, the shapes of the blue filters 12B and the red filters 12R are square or quadrangular, and the shapes of the sub-filters 12rr and the sub-filters 12bb are isosceles triangles. In addition, the blue filter 12B, the red filter 12R, the first combined filter 12X_1 and the second combined filter 12X_2 have the same area. The sub-filter 12rr and the sub-filter 12bb have the same area. Furthermore, the area of the blue filter 12B is equal to four times the area of the sub-filter 12rr.

In the color filter array 120, the red filter 12R is separated from the sub-filters 12bb by the sub-filters 12rr. Furthermore, the blue filter 12B is separated from the sub-filters 12rr by the sub-filters 12bb. In other words, the sub-filter 12rr is surrounded by the two sub-filters 12bb and the red filter 12R, and the sub-filter 12bb is surrounded by the two sub-filters 12rr and the blue filter 12B.

In the color filter array 120, the blue filter 12B and the red filter 12R are formed of different materials or coatings, and have different extinction coefficients for light in a specific wavelength range. In addition, the sub-filter 12bb and the sub-filter 12rr are formed of different materials or coatings, and have the same or different extinction coefficients for light in a specific wavelength range.

In some embodiments, the blue filter 12B is configured to transmit visible light corresponding to the relevant wavelength range of blue light. The red filter 12R is configured to transmit visible light corresponding to the relevant wavelength range of red light. The sub-filter 12bb is configured to transmit visible light corresponding to the relevant wavelength range of blue light and green light. The sub-filter 12rr is configured to transmit visible light corresponding to the relevant wavelength range of red light and green light.

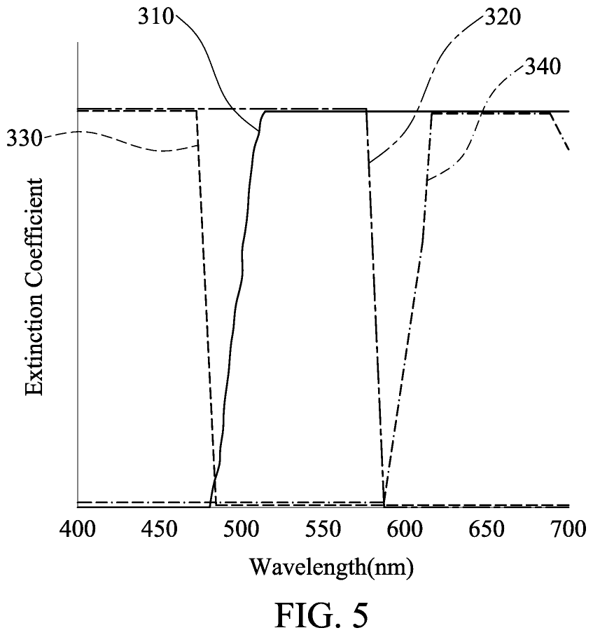

FIG. 5 shows a graph illustrating the extinction coefficients of the blue filter 12B, the red filter 12R, and the sub-filters 12bb and 12rr according to some embodiments of the invention. The curve 310 represents the extinction coefficient K_{B} of the blue filter 12B. The curve 320 represents the extinction coefficient K_{R} of the red filter 12R. The curve 330 represents the extinction coefficient Kᵣᵣ of the sub-filter 121T. The curve 340 represents the extinction coefficient K_{bb} of the sub-filter 12bb.

In some embodiments, for blue light with a wavelength range of 400 nm to 500 nm, the extinction coefficient K_{B} of the blue filter 12B and the extinction coefficient K_{bb} of the sub-filter 12bb are close to 0 (i.e., K_{B}≈0 and K_{bb}≈0), and the extinction coefficient K_{R} of the red filter 12R and the extinction coefficient Kᵣᵣ of the sub-filter 12rr are greater than 0 (i.e., K_{R}>0 and Kᵣᵣ>0). In other words, the light corresponding to the wavelength range of blue light can pass through the blue filter 12B and the sub-filter 12bb, but cannot pass through the red filter 12R and the sub-filter 12rr.

In some embodiments, for green light with a wavelength range of 500 to 600 nm, the extinction coefficient Kᵣᵣ of the sub-filter 12rr and the extinction coefficient K_{bb} of the sub-filter 12bb are close to 0 (i.e., Kᵣᵣ≈0 and K_{bb}≈0), and the extinction coefficient K_{R} of the red filter 12R and the extinction coefficient K_{B} of the blue filter 12B are greater than 0 (i.e., K_{R}>0 and K_{B}>0). In other words, the light corresponding to the wavelength range of green light can pass through the sub-filter 12rr and the sub-filter 12bb, but cannot pass through the red filter 12R and the blue filter 12B.

In some embodiments, for red light with a wavelength range of 600 to 700 nm, the extinction coefficient Kᵣᵣ of the sub-filter 12rr and the extinction coefficient K_{R} of the red filter 12R are close to 0 (i.e., Kᵣᵣ≈0 and K_{R}≈0), and the extinction coefficient K_{bb} of the sub-filter 12bb and the extinction coefficient K_{B} of the blue filter 12B are greater than 0 (i.e., K_{bb}>0 and K_{B}>0). In other words, light corresponding to the wavelength range of red light can pass through the red filter 12R and the sub-filter 12rr, but cannot pass through the blue filter 12B and the sub-filter 12bb.

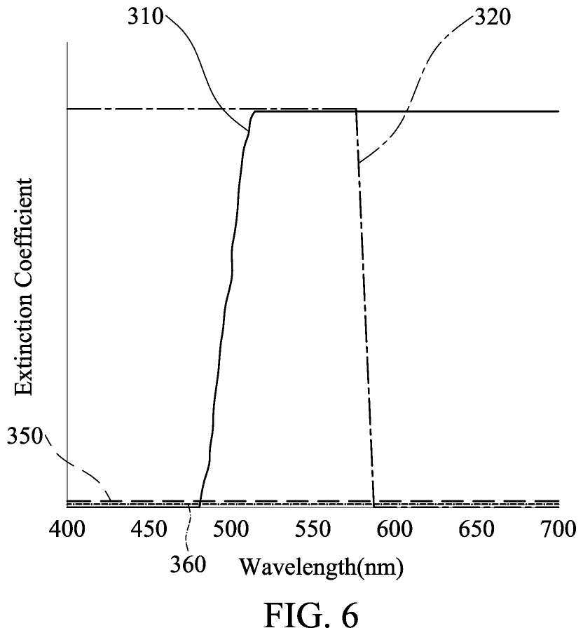

FIG. 6 shows a graph illustrating the extinction coefficients of the blue filter 12B, the red filter 12R, and the sub-filters 12bb and 121T according to some embodiments of the invention. The curve 310 represents the extinction coefficient K_{B} of the blue filter 12B. The curve 320 represents the extinction coefficient K_{R} of the red filter 12R. The curve 350 represents the extinction coefficient Kᵣᵣ of the sub-filter 12rr. The curve 360 represents the extinction coefficient K_{bb} of the sub-filter 12bb. Compared with FIG. 5, the extinction coefficient Kᵣᵣ of the sub-filter 12rr and the extinction coefficient K_{bb} of the sub-filter 12bb in FIG. 6 are substantially close to 0 in various wavelength ranges.

In the color filter array 120, the blue filter 12B and the red filter 12R have different refraction indexes for light in a specific wavelength range. In addition, the sub-filter 12bb and the sub-filter 12rr have similar or different refraction indexes for light in the same wavelength range.

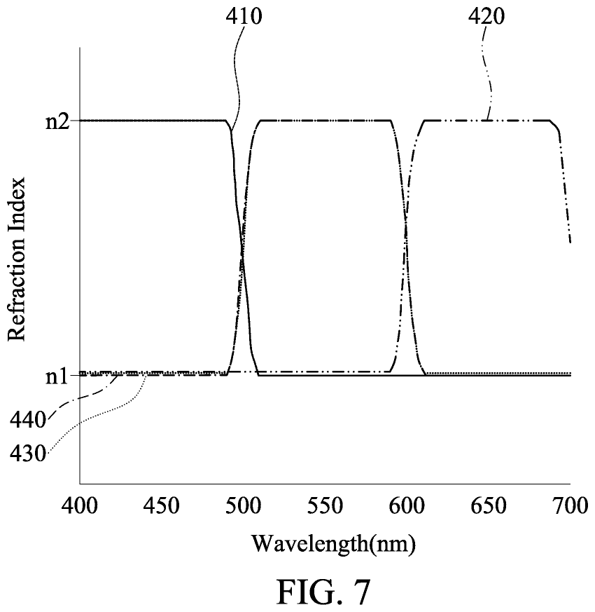

FIG. 7 shows a graph illustrating the refraction indexes of the blue filter 12B, the red filter 12R, and the sub-filters 12bb and 12rr according to some embodiments of the invention. The curve 410 represents the refraction index N_{B} of the blue filter 12B. The curve 420 represents the refraction index N_{R} of the red filter 12R. The curve 430 represents the refraction index Nᵣᵣ of the sub-filter 12rr. The curve 440 represents the refraction index N_{bb} of the sub-filter 12bb. In addition, in the embodiment of FIG. 7, the refraction index Nᵣᵣ is similar to the refraction index N_{bb}. In other embodiments, the refraction index Nᵣᵣ is different from the refraction index N_{bb}. In the different visible light bands in FIG. 7, the refraction indexes N_{B}, N_{R}, N_{bb}, and Nᵣᵣ have a corresponding relationship between the refraction values n1 and n2. However, the refraction values n1 and n2 in FIG. 7 are only examples, and are not intended to limit the invention.

In some embodiments, for blue light with a wavelength range of 400 nm to 500 nm, the refraction index N_{B} of the blue filter 12B is greater than or equal to the refraction index N_{bb} of the sub-filter 12bb (i.e., N_{B}≥N_{bb}). In addition, the refraction index N_{bb} of the sub-filter 12bb is greater than the refraction index N_{R} of the red filter 12R (i.e., N_{bb}>N_{R}). Furthermore, the refraction index N_{bb} of the sub-filter 12bb is greater than the refraction index Nᵣᵣ of the sub-filter 12rr (i.e., N_{bb}>Nᵣᵣ). In other words, when light corresponding to the wavelength range of blue light passes through the blue filter 12B and the sub-filter 12bb, the light is guided into the blue filter 12B and the sub-filter 12bb, and the light guided into the sub-filter 12bb will be refracted into the blue filter 12B.

In some embodiments, for green light with a wavelength range of 500 nm to 600 nm, the refraction index N_{bb} of the sub-filter 12bb is similar to the refraction index Nᵣᵣ of the sub-filter 12rr (i.e., N_{bb}≈Nᵣᵣ). In addition, the refraction index N_{bb} of the sub-filter 12bb is greater than the refraction index N_{B} of the blue filter 12B (i.e. N_{bb}>N_{B}) and greater than the refraction index N_{R} of the red filter 12R (i.e., N_{bb}>N_{R}). In other words, when light corresponding to the wavelength range of green light passes through the sub-filters 12bb and 12rr, the light is guided into the sub-filters 12bb and 12rr.

In some embodiments, for red light with a wavelength range of 600 nm to 700 nm, the refraction index N_{R} of the red filter 12R is greater than or equal to the refraction index Nᵣᵣ of the sub-filter 12rr (i.e., N_{B}≥Nᵣᵣ). In addition, the refraction index Nᵣᵣ of the sub-filter 12rr is greater than the refraction index N_{B} of the blue filter 12B (i.e., Nᵣᵣ>N_{B}). Furthermore, the refraction index Nᵣᵣ of the sub-filter 12rr is greater than the refraction index N_{bb} of the sub-filter 12bb (that is, Nᵣᵣ>N_{bb}). In other words, when light corresponding to the wavelength range of red light passes through the red filter 12R and the sub-filter 12rr, the light is guided into the red filter 12R and the sub-filter 12rr, and the light guided to the sub-filter 12rr will be refracted into the blue filter 12R.

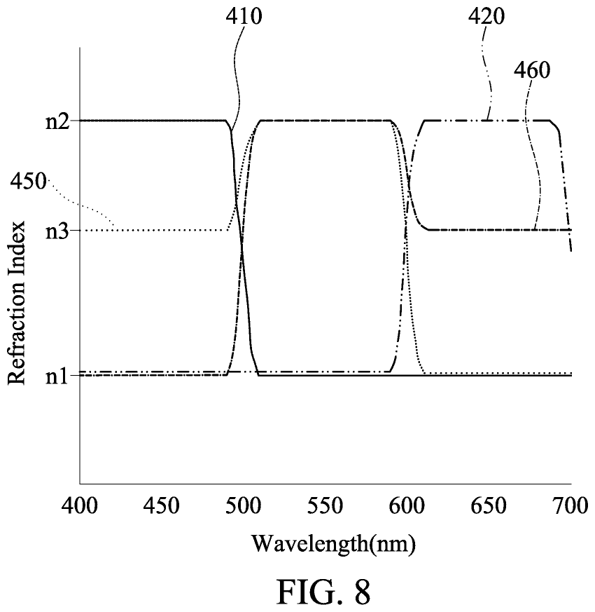

FIG. 8 shows a graph illustrating the refraction indexes of the blue filter 12B, the red filter 12R, and the sub-filters 12bb and 12rr according to some embodiments of the invention. The curve 410 represents the refraction index N_{B} of the blue filter 12B. The curve 420 represents the refraction index N_{R} of the red filter 12R. The curve 450 represents the refraction index N_{bb} of the sub-filter 12bb. The curve 460 represents the refraction index Nᵣᵣ of the sub-filter 12rr. Compared with the refraction index N_{bb} of the sub-filter 12bb and the refraction index Nᵣᵣ of the sub-filter 12rr with two refraction values n1 and n2 in FIG. 7, the refraction index N_{bb} of the sub-filter 12bb and the refraction index Nᵣᵣ of and the sub-filter 12rr in FIG. 8 have three refraction values n1, n2, and n3. In the different visible light bands in FIG. 8, the refraction indexes N_{B}, N_{R}, N_{bb}, and Nᵣᵣ have a corresponding relationship between the refraction values n1, n2, and n3. However, the refraction values n1, n2, and n3 in FIG. 8 are only examples, and are not intended to limit the invention.

As shown in FIGS. 7 and 8, for blue light with a wavelength range of 400 nm (or 420 nm) to 500 nm, the refraction index N_{B} of the blue filter 12B is greater than the refraction index N_{bb} of the sub-filter 12bb, the refraction index N_{R} of the red filter 12R, and the refraction index Nᵣᵣ of the sub-filter 12rr. Furthermore, for green light with a wavelength range of 500 nm to 600 nm, the refraction index N_{bb} of the sub-filter 12bb and the refraction index Nᵣᵣ of the sub-filter 12rr are greater than the refraction index N_{B} of the blue filter 12B and the refraction index N_{R} of the red filter 12R. Moreover, for red light with a wavelength range of 600 nm to 700 nm (or 680 nm), the refraction index N_{R} of the red filter 12R is greater than the refraction index Nᵣᵣ of the sub-filter 12rr, and the refraction index N_{B} of the blue filter 12B and the refraction index N_{bb} of the sub-filter 12bb.

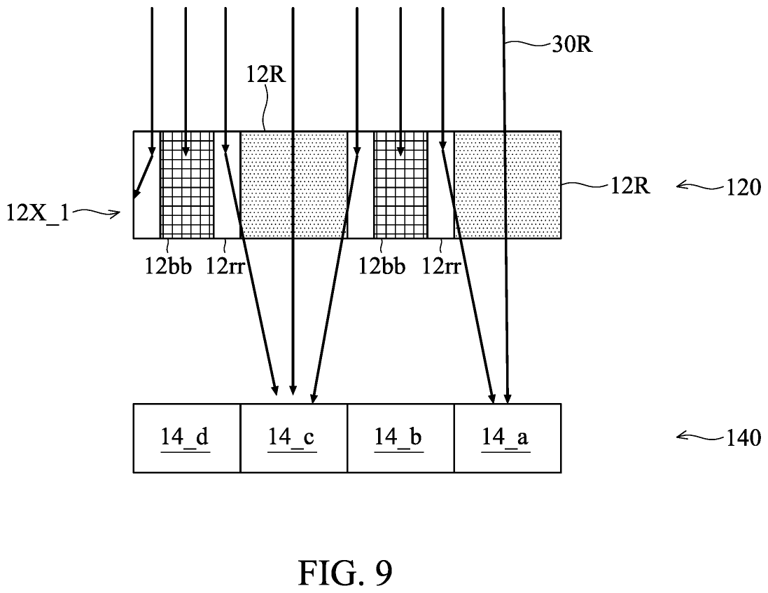

FIG. 9 shows a cross-sectional view along the line A-AA of the color filter array 120 in FIG. 4 according to some embodiments of the invention. In the embodiment, the image-sensing cells 14_a and 14_c of the image sensor 140 are disposed directly below the red filter 12R, and the image-sensing cells 14_b and 14_d of the image sensor 140 are disposed directly below the first combined filter 12X_1. In FIG. 9, the red light 30R passes through the red filter 12R and reaches the underlying image-sensing cells 14_a and 14_c. In addition, the red light 30R is refracted to the adjacent red filter 12R through the sub-filter 12rr, and then reaches the underlying image-sensing cells 14_a and 14_c through the red filter 12R. In FIG. 9, the red light 30R cannot pass through the sub-filter 12bb to reach the underlying image-sensing cells 14_b and 14_d, so the signal intensity detected by the image-sensing cells 14_b and 14_d will be very low. For each of the image-sensing cells 14_a and 14_c, in addition to receiving the red light 30R from the corresponding red filter 12R (i.e., the red filter 12R directly above), it also receives the red light 30R from the surrounding sub-filters 12rr, so that the image-sensing cells 14_a and 14_c are capable of detecting higher signal strength. Therefore, when the image-sensing device with the color filter array 120 is in a low-light condition, the image-sensing cells of the image-sensing device can sense higher signal strength with the refracted light from the surrounding filters (that is, more light sources).

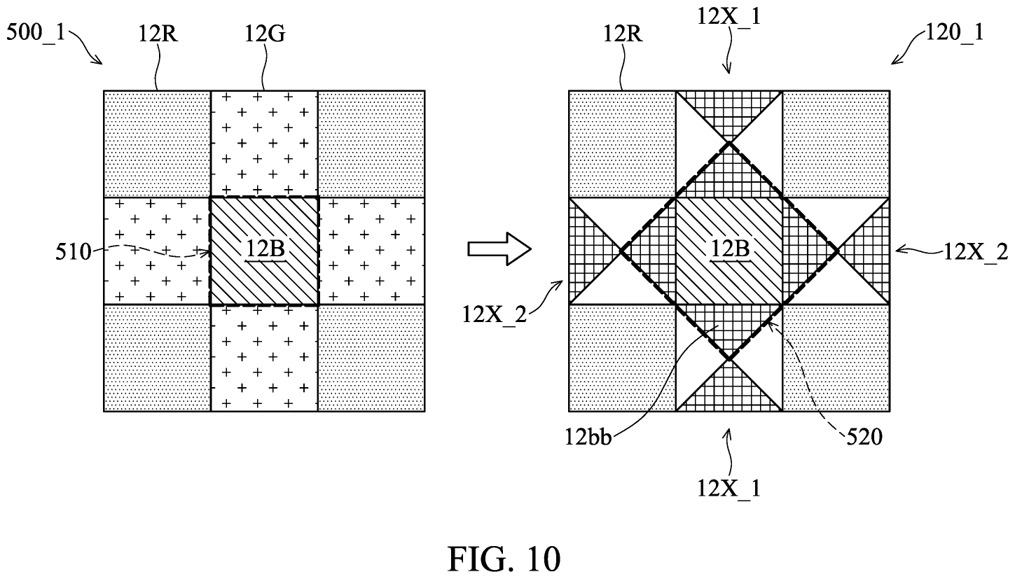

FIG. 10 shows that the green filters 12G of the traditional color filter array 500_1 are replaced with the first combined filter 12X_1 and the second combined filter 12X_2 to obtain the color filter array 120_1 according to the embodiments of the invention. For simple explanation, the traditional color filter array 500_1 and the color filter array 120 only display 3×3 filters. In the traditional color filter array 500_1, the blue filter 12B is arranged at the center of the array 500_1, and the red filter 12R is arranged at the four corners of the array 500_1. In addition, four green filters 12G are arranged on the four sides of the blue filter 12B. Therefore, in the traditional color filter array 500_1 the blue light can only pass through the area of the blue filter 12B, as shown in dotted box 510.

In FIG. 10, two green filters 12G located on the upper and lower sides of the blue filter 12B are replaced with the first combined filters 12X_1, and two green filters 12G located on the left and right sides of the blue filter 12B are replaced with the second combined filters 12X_2, so as to obtain the color filter array 120_1. In the color filter array 120_1, the four sub-filters 12bb are disposed on the four sides of the blue filter 12B. Therefore, in the color filter array 120_1, for blue light, in addition to the area of the blue filter 12B, it can pass the area of the sub-filter 12bb, as shown in dotted box 520. In other words, the area of the color filter array 120_1 that the blue light can pass through becomes twice that of the traditional color filter array 500_1, that is, the area of the dotted box 520 is equal to twice the area of the dotted box 510. Therefore, the image-sensing cells located under the color filter array 120_1 can sense the higher signal strength.

Moreover, a traditional color filter array may be formed by the red filters 12R, the blue filters 12B, and the white filters (not shown). As described above, the white filters can be replaced by the first combined filter 12X_1 and the second combined filter 12X_2 described in the embodiment of the invention.

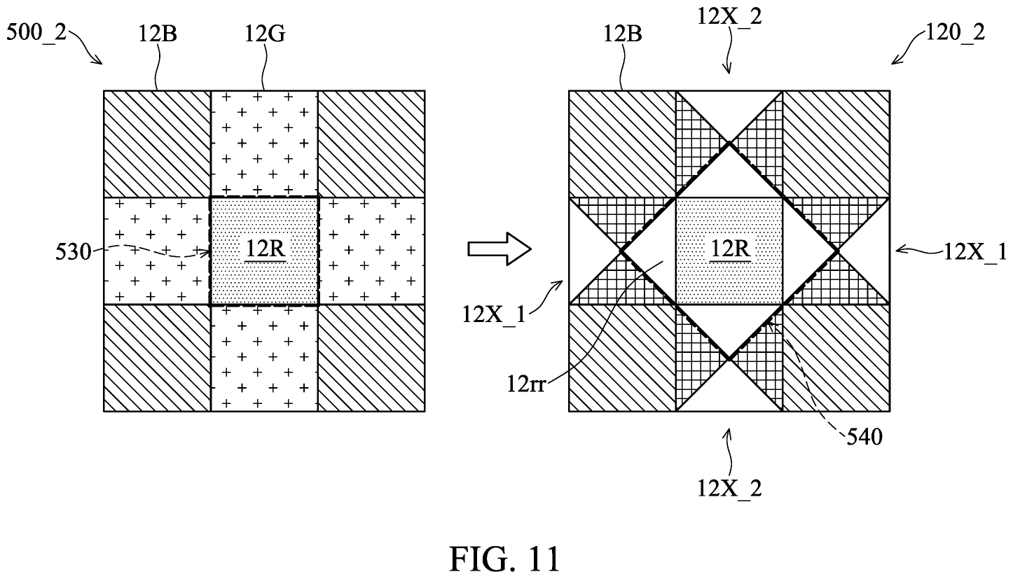

FIG. 11 shows that the green filters 12G of the traditional color filter array 500_2 are replaced with the first combined filter 12X_1 and the second combined filter 12X_2 to obtain the color filter array 120_2 according to the embodiment of the invention. For the sake of simplicity, the traditional color filter array 500_2 and the color filter array 120 only display 3×3 filters. In the traditional color filter array 500_2, the red filter 12R is arranged at the center of the array 500_2, and the blue filters 12B are arranged at the four corners of the array 500_2. In addition, four green filters 12G are disposed on the four sides of the red filter 12R. Therefore, in the traditional color filter array 500_1, the red light can only pass through the area of the red filter 12R as shown in dotted box 530.

In FIG. 11, the two green filters 12G located on the upper and lower sides of the red filter 12R are replaced with the second combined filters 12X_2, and the two green filters 12G located on the left and right of the red filter 12R are replaced with the first combined filters 12X_1, and then the color filter array 120_2 is obtained. In the color filter array 120_2, the four sub-filters 12rr are arranged on the four sides of the red filter 12R. Therefore, in the color filter array 120_2, for the red light, in addition to the area of the red filter 12R, it can pass through the area of the sub-filter 12rr, as shown in dotted box 540. In other words, the area of the color filter array 120_2 that the red light can pass through becomes twice that of the traditional color filter array 500_2, i.e., the area of the dotted box 540 is equal to twice the area of the dotted box 530. Therefore, the image-sensing cells located under the color filter array 120_2 can sense higher signal strength.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An image-sensing device, comprising:
a substrate;
an image sensor array formed over the substrate, and comprising a plurality of image-sensing cells;
a micro lens array formed over the image sensor array, and comprising a plurality of micro lenses; and
a color filter array formed between the micro lens array and the image sensor array, and comprising a plurality of blue filters, a plurality of red filters, a plurality of first combined filters and a plurality of second combined filters,
wherein each of the first combined filters and each of the second combined filters comprise two first sub-filters and two second sub-filters,
wherein the first sub-filters and the second sub-filters have a similar extinction coefficient in a first specific wavelength range, and have different extinction coefficients in a second specific wavelength range,
wherein areas of each of the first sub-filters and each of the second sub-filters are smaller than areas of each of the blue filters and each of the red filters.

2. The image-sensing device as claimed in claim 1, wherein shapes of the blue filter and the red filter are square, and shapes of the first sub-filter and the second sub-filter are isosceles triangles.

3. The image-sensing device as claimed in claim 2, wherein the blue filter and the red filter have the same area, and total area of two of the first sub-filters and two of the second sub-filters is equal to the area of the blue filter.

4. The image-sensing device as claimed in claim 1, wherein the blue filter is configured to transmit light in a first wavelength range corresponding to blue light, the red filter is configured to transmit light in a second wavelength range corresponding to red light, the first sub-filter is configured to transmit light in a third wavelength range corresponding to blue light and green light, and the second sub-filter is configured to transmit light in a fourth wavelength range corresponding to red light and green light.

5. The image-sensing device as claimed in claim 1, wherein the blue filters and the first combined filters are alternately arranged in odd-numbered rows of the color filter array, and the red filters and the second combined filters are alternately arranged in the even-numbered rows of the color filter array.

6. The image-sensing device as claimed in claim 1, wherein each of the blue filters is surrounded by the first sub-filters, and each of the red filters is surrounded by the second sub-filters.

7. The image-sensing device as claimed in claim 1, wherein each of the blue filters is separated from the second sub-filters by the first sub-filters, and each of the red filters is separated from the first sub-filters by the second sub-filters.

8. The image-sensing device as claimed in claim 1, wherein each of the first sub-filters is surrounded by one of the blue filters and two of the second sub-filters, and each of the second sub-filters is surrounded by one of the red filters and two of the first sub-filters.

9. The image-sensing device as claimed in claim 1, wherein each of the blue filters, each of the red filters, each of the first combined filters, and each of the second combined filters corresponds to an individual micro lens, and each of the micro lenses corresponds to an individual image-sensing cell.

10. The image-sensing device as claimed in claim 1, wherein in a first wavelength range corresponding to blue light, a refraction index of the blue filter is greater than refraction indexes of the red filter, the first sub-filter and the second sub-filter, wherein in a second wavelength range corresponding to red light, the refraction index of the red filter is greater than the refraction indexes of the blue filter, the first sub-filter and the second sub-filter, and in a third wavelength range corresponding to green light, the refraction indexes of the first sub-filter and the second sub-filter are greater than the refraction indexes of the blue filter and the red filter.

11. An image-sensing device, comprising:
a substrate;
an image sensor array formed over the substrate, and comprising a plurality of image-sensing cells;
a micro lens array formed over the image sensor array, and comprising a plurality of micro lenses, wherein each of the micro lenses corresponds to an individual image-sensing cell; and
a color filter array formed between the micro lens array and the image sensor array, and comprising a plurality of blue filters, a plurality of red filters, a plurality of first combined filters and a plurality of second combined filters,
wherein each of the first combined filters and each of the second combined filters comprise two first sub-filters and two second sub-filters,
wherein each of the first combined filters, each of the second combined filters, each of the blue filters and each of the red filters have the same area,
wherein each of the blue filters is surrounded by the first sub-filters, and each of the red filters is surrounded by the second sub-filters.

12. The image-sensing device as claimed in claim 11, wherein the blue filter is disposed on a first image-sensing cell of the image-sensing cells, the red filter is disposed on a second image-sensing cell of the image-sensing cells, and the first combined filter is disposed on a third image-sensing cell of the image-sensing cells, and the second combined filter is disposed on a fourth image-sensing cell of the image-sensing cells.

13. The image-sensing device as claimed in claim 12, wherein the shapes of the blue filter and the red filter are square, and the shapes of the first sub-filter and the second sub-filter are isosceles triangles.

14. The image-sensing device as claimed in claim 13, wherein two of the first sub-filters and two of the second sub-filters disposed on the third image-sensing cell are arranged and combined into a first square, and two of first sub-filters and two of the second sub-filters disposed on the fourth image-sensing cell are arranged and combined into a second square.

15. The image-sensing device as claimed in claim 11, wherein the first sub-filter and the second sub-filter have similar extinction coefficients in a first specific wavelength range, and have different extinction coefficients in a second specific wavelength range.

16. The image-sensing device as claimed in claim 11, wherein the blue filter is configured to transmit light in a first wavelength range corresponding to blue light, the red filter is configured to transmit light in a second wavelength range corresponding to red light, the first sub-filter is configured to transmit light in a third wavelength range corresponding to blue light and green light, and the second sub-filter is configured to transmit light in a fourth wavelength range corresponding to red light and green light.

17. The image-sensing device as claimed in claim 11, wherein the first sub-filter and the second sub-filter have the same area.

18. The image-sensing device as claimed in claim 11, wherein each of the blue filters is separated from the second sub-filters by the first sub-filters, and each of the red filters is separated from the first sub-filters by the second sub-filters.

19. The image-sensing device as claimed in claim 11, wherein each of the first sub-filters is surrounded by one of the blue filters and two of the second sub-filters, and each of the second sub-filters is surrounded by one of the red filters and two of the first sub-filters.

20. The image-sensing device as claimed in claim 11, wherein in a first wavelength range corresponding to blue light, a refraction index of the blue filter is greater than refraction indexes of the red filter, the first sub-filter and the second sub-filter, wherein in a second wavelength range corresponding to red light, the refraction index of the red filter is greater than the refraction indexes of the blue filter, the first sub-filter and the second sub-filter, and in a third wavelength range corresponding to green light, the refraction indexes of the first sub-filter and the second sub-filter is greater than the refraction indexes of the blue filter and the red filter.
